(19) United States
(12) Patent Application Publication
(10) Pub. No.: US 2015/0004331 A1
(43) Pub. Date: Jan. 1, 2015

(54) METHOD AND DEVICE FOR PASSIVATING SOLAR CELLS WITH AN ALUMINIUM OXIDE LAYER

(71) Applicant: SUNGULUS TECHNOLOGIES AG, Kahl am Main (DE)

(72) Inventors: Torsten Dippell, Langen (DE); Björn Roos, Freigericht (DE); Oliver Hohn, Grundau (DE); Thorsten Dullweber, Bad Pyrmont (DE); Nils-Peter Harder, Hameln (DE); Michael Seibert, Hameln (DE)

(73) Assignee: Singulus Technologies AG, Kahl am Main (DE)

(21) Appl. No.: 14/377,317

(22) PCT Filed: Feb. 6, 2013
(86) PCT No.: PCT/EP2013/052298

§ 371 Date: Aug. 7, 2014

(30) Foreign Application Priority Data
Feb. 9, 2012 (DE) 10 2012 201 953.7

(51) Int. Cl. C23C 16/513

(52) U.S. Cl. CPC C23C 16/513
USPC 427/576; 118/723 E

(57) ABSTRACT

A method for coating a substrate with an AlOₓ layer, in particular an Al₂O₃ layer, comprising the following method steps: (a) providing an inductively coupled plasma source (ICP source) having a reaction chamber and at least one RF inductor, (b) introducing an aluminium compound, preferably trimethylaluminium (TMA) into the ICP source, (c) introducing oxygen and/or an oxygen compound as reactive gas into the ICP source and inductively coupling of energy into the ICP source for forming a plasma, and (d) depositing the AlOₓ layer on the substrate. The invention also relates to a coating assembly for depositing thin layers on a substrate, in particular for carrying out the above method. The coating assembly comprises an inductively coupled plasma source (ICP) having a reaction chamber and at least one RF inductor, a substrate holder for arranging the substrate in the reaction chamber and channels for introducing the aluminium compound and a reactive gas in the ICP source. The substrate is arranged in the reaction chamber such that the substrate surface to be coated faces the ICP source.

### BACKGROUND

1. Field of the Disclosure

The present disclosure relates to a method and system for coating a substrate with an aluminium oxide layer, in particular for surface passivation of solar cells.

2. Discussion of the Background Art

Due to unbound states at the surface of, e.g., a semiconductor, electrons and holes can recombine or pollution (e.g., humidity) can accumulate. Consequently, the recombination process for electronic components in unbound states, such as semiconductor elements and/or solar cells, can be detrimental and reduce the lifetime of these components. Moreover, the mode of operation of these components is not exactly predictable and calculable due to possible recombination processes at the surfaces.

In view of the above reasons, an attempt was made to provide the surfaces of such components with a coating serving as surface passivation. Such passivation layers are of particular interest for, e.g., highly efficient solar cells (e.g., rear side passivation of a PERC (passivated emitter and rear cell) solar cell or the front side of an n-type solar cell).

DE-A1-102007054384 suggested, e.g., that for surface passivation a dielectric double layer be used for passivating a solar cell. To this end the first layer was a thin aluminium oxide layer formed from an aluminium-containing gas through sequential vapour deposition (atomic layer deposition, ALD) while the second, thicker layer contained silicon nitride or silicon oxide or silicon carbide and was formed by means of plasma enhanced chemical vapour deposition (PECVD).

Although such methods provide quite good results regarding the quality of the rear side passivation in the crystalline solar cell production, a high throughput of cells per hour while at the same time using little aluminium-containing gas is scarcely possible.

It is the object of the present disclosure to provide a method and a system or a coating assembly, which is suitable for producing surface-passivated components with high throughput and low usage of process gases such as aluminium-containing gas and at the same time to not relinquish a high layer quality.

### SUMMARY

The disclosure is based on the concept to use an inductively coupled plasma (ICP) for depositing a passivation layer, e.g., aluminium oxide.

Thus, for instance, a high conversion of the reaction products and a high coating rate can be achieved. In such a way, also the turnover rate for high-quality layers (low defect rate and good homogeneity also on large surfaces) can be increased.

The disclosure particularly relates to a method for coating a substrate with an AlOₓ layer, in particular Al₂O₃ layer. An inductively coupled plasma source (ICP source) having a reaction chamber and at least one RF inductor is provided. An aluminium compound, preferably trimethyl aluminium (TMA) and/or dimethylaluminium isopropoxide (DMAI), and oxygen and/or an oxygen compound as reactive gas are introduced into the ICP source. For forming a plasma, energy is inductively coupled into the ICP source and the AlOₓ layer is deposited on the substrate.

A plasma comprises free-to-move electrons, ions, molecules, neutrals and radicals. A plasma can be used, e.g., to transform non-reactive molecules, i.a., into electrically charged and/or excited, reactive molecules and/or radicals, wherein the reactivity and the distribution of the plasma can be controlled, e.g., by applied electric and/or magnetic fields.

According to the present disclosure, the energy necessary for plasma generation is coupled into the reaction chamber filled with process gases via a radiofrequency (RF) inductor.

For producing electronic components, e.g., for the semiconductor and/or solar cell industries, it is advantageous to use a low ion-energy plasma. Specific reaction gases can be introduced therefor, e.g., via channels, into the reaction chamber.

The excited gases can react with layer-forming substances (e.g., TMA, DMAI, (CH₃)₃Al or SiH₄), wherein layers of new substances form at the substrate surface in which elements from all reaction partners may be present.

For aluminium oxide coating, oxygen gas (O₂) may be used for instance, and for producing a silicon nitride layer a nitrogenous reactive gas, such as NH₃, may be used.

Advantageously, the inductively coupled energy of an ICP plasma source can lead to a higher plasma density. Thus, the method can be carried out at low pressure so that the deposited layer exhibits a good homogeneity over a relatively large area (e.g., in the range of 100 mm×100 mm, 150 mm×150 mm, 156 mm×156 mm or more) with particular layer composition and, at the same time, at a high coating rate.

### BRIEF DESCRIPTION OF THE DRAWINGS

The disclosure is described in further detail on the basis of the drawings as follows:

FIG. 1 is a schematic view of a process station of an ICP-PECVD coating assembly,

FIG. 2 is a schematic view of a plurality of process stations of an ICP-PECVD coating assembly, and

FIG. 3 is a schematic view of a process station of an ICP-PECVD coating assembly with dielectric partition wall.

### DETAILED DESCRIPTION OF THE PREFERRED EMBODIMENT

In one embodiment, the plasma density and the ion energy are controlled independently of each other. For instance, the plasma density may be at least 1×10¹¹ ions/cm³, preferably 1×10¹² ions/cm³ to 9×10¹³ ions/cm³. Independent thereof, the ion energy in one embodiment can be between 1 and 30 eV, preferably less than 20 eV. As the ion energy and the plasma density can be controlled independently of each other, it is possible to obtain high plasma densities without harming the substrate surface or the substrate as such, in particular the emitter.

In one embodiment, there is a vacuum of 10⁻⁴ to 10⁻¹ mbar, preferably of 10⁻³ to 5*10⁻² mbar, in the reaction chamber. This pressure in the reaction chamber enables the production of very homogeneous layers also on large surfaces so that in this manner the throughput of the coated components can be increased.

In one embodiment, the inductive coupling of energy with a frequency of 1-60 MHz, preferably with 13.56 MHz, is carried out. Due to the direct energy coupling by means of the RF inductor, a high plasma density and thus a high coating rate can be achieved.

In one embodiment, the substrate consists of silicon. Silicon is preferably used for the production and/or coating of semiconductors and/or solar cells. In particular, the use of crystalline silicon can be advantageous since crystalline silicon solar cells are prone to little loss due to degradation especially during operation over a longer period of time of several years (up to 20 years or longer).

In one embodiment, a further layer, in particular a dielectric, can be deposited on the aluminium oxide layer. To this end, according to the method, the substrate provided with the AlOₓ layer either remains in the same chamber or is transported in a further reaction chamber with a further ICP source. Preferably a silicon compound is introduced into the second ICP source and nitrogen or oxygen or a hydrocarbon compound (such as, e.g., CH₂) and/or a nitrogen compound or an oxygen compound or a compound of a hydrocarbon compound is introduced as reactive gas into the second ICP source. For forming a plasma, energy is coupled into the second ICP source and then a respective SiN_{y} or SiOₓ or SiC_{z} layer is deposited on the AlOₓ layer.

In this way, for instance, a passivation stack of two or more layers can be easily formed on the substrate. In particular, the further (second) reaction chamber can be directly arranged next to the first reaction chamber in the same coating assembly. Thus, in a further process step in the same coating assembly, a further layer, in particular of a different material, can be applied onto the substrate which has just been coated with the first layer without complex inward and/or outward transfer of the (coated) substrate.

The present disclosure also relates to a coating assembly for depositing thin layers on a substrate, in particular for carrying out one of the above methods. The coating assembly can be particularly suitable for fulfilling the above-described process parameters.

According to the disclosure, the coating assembly comprises an inductively coupled plasma source (ICP) having a reaction chamber and at least one RF inductor, a substrate holder for arranging a substrate, in particular a plurality of substrates, in the reaction chamber and channels for introducing the aluminium compound and a reactive gas into the ICP source. The substrate is arranged such in the reaction chamber that the substrate surface to be coated faces the ICP source.

The inductively coupled plasma source comprises the reaction chamber and at least one inductor being coupled to a radiofrequency power source. Thus, the energy necessary for the creation of the plasma can be directly coupled into the reaction chamber. Moreover, preferably channels for introducing reactive gas and/or for introducing, e.g., a fluid precursor (such as, e.g., TMA) into the plasma source are provided. Arranging the substrate such that the substrate surface to be coated faces the plasma source enables an optimisation of the coating rate and thus an increase in the throughput of the coated components.

According to one embodiment, the coating assembly comprises at least a second inductively coupled plasma source (ICP) having a reaction chamber and at least one RF inductor and channels for introducing a silicon compound and a reactive gas into the second/further ICP source(s).

Preferably, the coating assembly can be designed such that it comprises a plurality of process stations which are provided with ICP sources and corresponding reaction chambers and channels. In one embodiment, the coating assembly also comprises transport mechanisms so that particularly a coated substrate can be introduced from a first into a second process station, in particular into a second plasma source having a reaction chamber. In the second process station/source/reaction chamber a further coating may take place, in particular for forming a different layer (compared to the first layer). Moreover, further coatings in further process stations/sources/reaction chambers can be provided.

In an embodiment, the inductor of the ICP source or ICP sources is arranged outside of the corresponding reaction chamber and separated by it by means of a dielectric partition wall. Preferably, the dielectric wall separates the reaction chamber from the area of the inductor with the radiofrequency power source such that it particularly presents a protection for the inductor and the plasma can form in a controlled and directed manner.

The methods and coating assembly described can be used, e.g., for passivation, in particular rear side passivation of solar cells, preferably of crystalline solar cells.

The method of the disclosure and the corresponding coating assembly enable the production of high-quality, low-defect homogeneous layers (low pressure). Moreover, due to the high dissociation of oxygen and the high conversion rate of the aluminium-containing gas, in particular TMA, and/or DMAI, in the source, a high throughput of coated substrates, e.g., solar cells having a high cell efficiency, is also achieved while at the same time the usage of TMA and/or DMAI is low. Thus, the material costs per wafer or per watt decrease considerably.

A further advantage over already known methods or coating assemblies consists in that these methods can be carried out in one single assembly (e.g., with a plurality of reaction chambers having the same pressure or different pressures, and/or with suitable transport mechanisms between the individual chambers): Thus, e.g., the entire rear side layer stack from an aluminium oxide and a silicon nitride layer can happen in one platform (such a platform is known, e.g., from DE 10 2009 018 700), which is not possible with an ALD method and corresponding ALD assembly. In an embodiment, cyclic operation of the method of the disclosure and of the coating assembly of the disclosure is possible. For example, in that way at least one substrate can be in a first reaction chamber (or in another process station) while at the same time at least a further substrate is in a second reaction chamber (or in still another process station) and so on. Thus, it is no longer necessary that a single substrate or a single group of substrates undergoes a complete coating process in the assembly before the coating assembly is filled for coating with a next substrate or a next group of substrates: As soon as the first process step is terminated, e.g., in a first chamber, the substrate (or the group of substrates) can be transported in another chamber for further processing, while preferably at the same moment the first chamber is filled with a next substrate or a next group of substrates and so on. For example, a substrate or a group of substrates can undergo the various stations of the coating assembly in a circle in cyclic operation. Thus, the cycle time reduces, which in turn leads to a higher throughput, e.g., in cyclic operation without discharging or unloading.

Some of the above-described process parameters, in particular the ones independent of each other, especially for aluminium oxide coating, can be summarised as follows:

Pressure: 10⁻⁴ to 10⁻¹ mbar, preferably ranging from 10⁻³ to 5*10⁻² mbar

Substrate temperature: room temperature up to 450° C.

Radiofrequency: 1-60 MHz, preferably 13.56 MHz

Plasma power: 0.5 to 10 kW, preferably 3.5 to 6 kW

Ion energy: 1 eV to 30 eV, preferably less than 20 eV

Plasma density: at least 1×10¹¹ ions/cm³, preferably 1×10¹² ions/cm³ to 9×10¹³ ions/cm³

Degree of ionisation: up to 50%

Degree of dissociation: molecules of 2 atoms (O₂) up to 80%

Plasma quality: particle-free plasma beam by means of low pressure

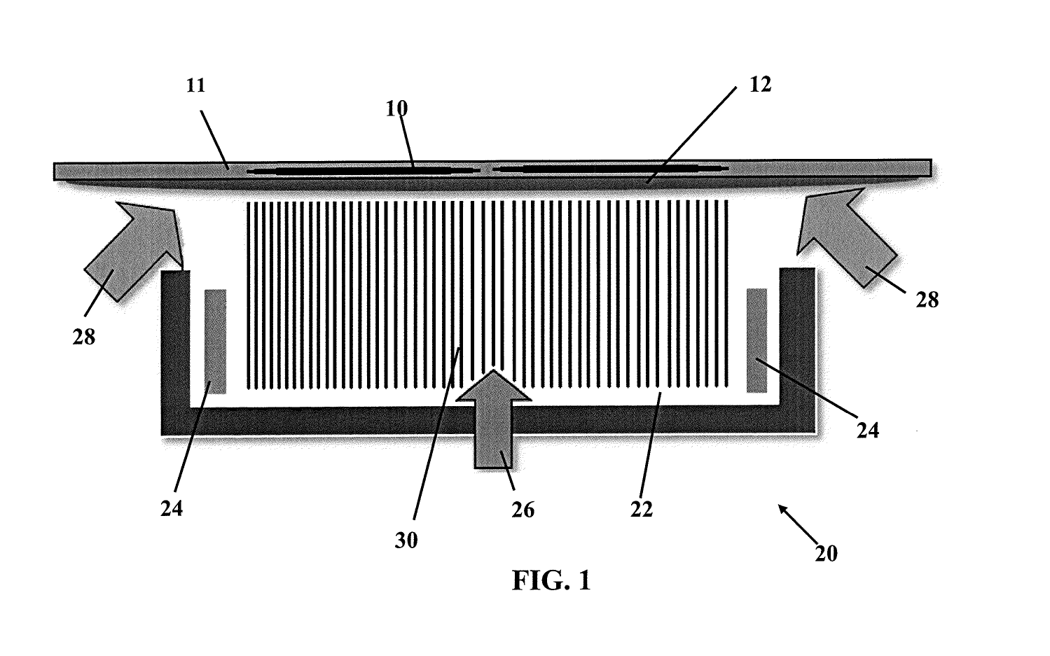

FIG. 1 shows a schematic cross-section through a part, in particular a process station, a coating assembly with a substrate holder 11 and the substrates 10. The process station comprises an ICP source 20 below the substrate holder 11 with the substrates 10 with a reaction chamber 22 and at least one circumferential RF inductor 24. In this embodiment, the RF inductor 24 is located at the lateral inner walls of the ICP source and thus defines the lateral outlines of the reaction chamber 22. The ICP source further comprises channels 28 through which a fluid precursor, e.g., TMA and/or DMAI, can be introduced into the reaction chamber. A reactive gas, e.g., oxygen, can also be introduced into the chamber 22 via one of these channels or a further channel 26.

Following the direct inductive coupling of energy, a plasma 30 is created which is formed towards the lower surface of the substrate 10 to be coated. Eventually, a thin layer 12, e.g., of an aluminium oxide, can thus be deposited on the substrate 10.

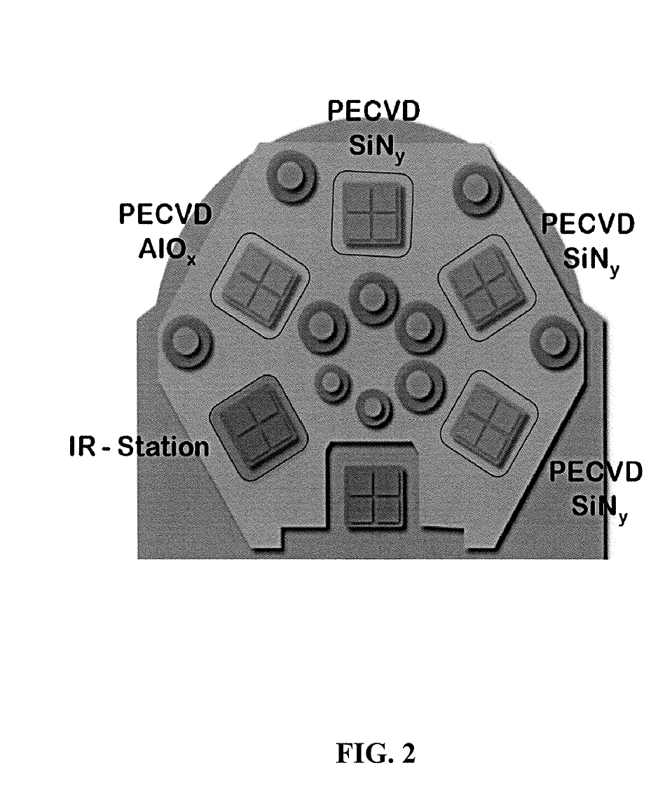

FIG. 2 shows a schematic view of a plurality of process stations. Next to an IR station for heating-up the substrate, a plurality of ICP sources are located which, e.g., can be reached by means of transport mechanisms clockwise one after the other and/or in arbitrary order with the substrate. For monitoring the substrate temperature at least one temperature sensor (not shown) can be provided

As an alternative, it is also possible that the substrate remains in a holder and the individual stations/sources/chambers may be attached to one side of the substrate (e.g., by turning the plane of the chambers parallel to the substrate plane) for coating of the substrate.

It is possible to coat a substrate in an assembly with different materials. For example, at first an aluminium oxide layer can be deposited on the substrate using TMA and/or DMAI as precursor and oxygen as reactive gas and, afterwards, a silicon nitride layer can be deposited on the aluminium oxide layer using SiH₄ as precursor and NH₃ as reactive gas.

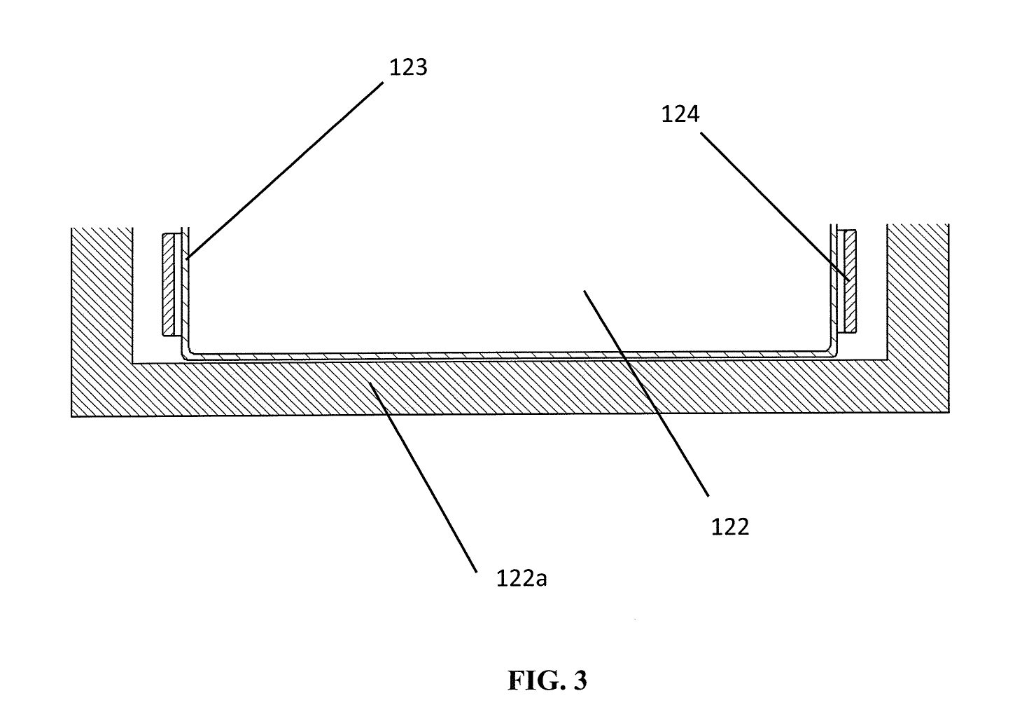

FIG. 3 shows a schematic cross-section through a part, in particular a process station, of a coating assembly. In one embodiment, the process station can basically also comprise the features of the process station of FIG. 1 and it shows a lower chamber wall 122a. Contrary to FIG. 1, the ICP source in FIG. 3 has a dielectric partition wall 123 separating the RF inductor 124 from the reaction chamber 122. In other words, the outer dimensions of the dielectric partition wall 123 can define at least a side wall of the reaction chamber and/or may be arranged trough-like and/or annularly in the source. In particular, the dielectric partition wall can represent a protection for the inductor and serve for a formation of the plasma which is controlled and directed to the substrate surface to be coated.

Thus, the method of the disclosure and the corresponding coating assembly enable the production of high-quality layers at low process pressure and low material costs. A further advantage vis-à-vis already known methods or coating assemblies consists in that these methods can be carried out in one single assembly so that the cycle time is reduced and the throughput is increased.

What is claimed is:

1. Method for coating a substrate with an AlOₓ layer, in particular an Al₂O₃ layer, comprising the following method steps:
(a) providing an inductively coupled plasma source (ICP source) having a reaction chamber and at least one RF inductor,
(b) introducing an aluminium compound into the ICP source,
(c) introducing oxygen and/or an oxygen compound as reactive gas into the ICP source and inductively coupling of energy into the ICP source for forming a plasma, and
(d) depositing the AlOₓ layer on the substrate.

2. The method according to claim 1, wherein the substrate of comprises silicon.

3. The method according to claim 1, wherein the plasma density is at least 1×10¹¹ ions/cm³.

4. The method according to claim 1, wherein the ion energy ranges from between about 1 to about 30 eV.

5. The method according to claim 1, wherein there is a vacuum of 10⁻⁴ to 10⁻¹ mbar, in the reaction chamber.

6. The method according to claim 1, wherein the inductive coupling of energy is carried out with a frequency of between about 1 to about 60 MHz.

7. The method according to claim 1, further comprising:
(e) depositing an SiN_{y} layer on the AlOₓ layer in the reaction chamber using the ICP source or a further ICP source, or in a further reaction chamber using a further ICP source.

8. The method according to claim 7, wherein step (e) comprises the following steps:
(e1) introducing a silicon compound into the ICP source or in the further ICP source, and
(e2) introducing nitrogen and/or a nitrogen compound as reactive gas into this ICP source and inductively coupling of energy into this ICP source for forming a plasma.

9. The method according to claim 1, wherein the substrate temperature is in the range between about room temperature to about 450° C.

10. The method according to claim 1, wherein the plasma power is in the range between about 0.5 to about 10 kW.

11. The method according to claim 1, wherein the plasma density and the ion energy are controlled independently from each other.

12. Coating assembly for depositing thin layers on a substrate comprising:
(a) an inductively coupled plasma source (ICP) having a reaction chamber and at least one RF inductor,
(b) a substrate holder for arranging at least one substrate in the reaction chamber, and
(c) channels for introducing the aluminium compound and a reactive gas into the ICP source,
(d) wherein the substrate is arranged in the reaction chamber such that the surface of the substrate to be coated faces the ICP source.

13. The coating assembly according to claim 12, comprising:
(e) at least one further inductively coupled plasma source (ICP) each having a reaction chamber and at least one additional RF inductor, and
(f) channels for introducing a silicon compound and a reactive gas into the further ICP source(s).

14. The coating assembly according to claim 12, wherein the RF inductor of the ICP source or ICP sources is arranged outside of the corresponding reaction chamber and is separated from it by means of a dielectric partition wall.

15. A method for passivation solar cells, said method comprises coating a substrate with an AlOₓ layer, in particular an Al₂O₃ layer, comprising the following method steps:
(a) providing an inductively coupled plasma source (ICP source) having a reaction chamber and at least one RF inductor,
(b) introducing an aluminium compound into the ICP source,
(c) introducing oxygen and/or an oxygen compound as reactive as into ICP source and inductively coupling of energy into the ICP source for forming a plasma, and
(d) depositing the AlOₓ layer on the substrate.

16. The method according to claim 3, wherein the plasma density in the range between about 1×10¹² ions/cm³ to about 9×10¹³ ions/cm³.

17. The method according to claim 5, wherein said vacuum is in the range between about 10⁻³ to about 5×10⁻² mbar, in the reaction chamber.

18. The method according to claim 6, wherein the inductive coupling of energy is carried out at a frequency of about 13.56 MHz.

19. The method according to claim 10, wherein the plasma power is in the range between about 3.5 to about 6 kW.
